(19) United States
(12) Patent Application Publication
(10) Pub. No.: US 2026/0068657 A1
(43) Pub. Date: Mar. 5, 2026

(54) CHIP PACKAGE AND SUBSTRATE THEREOF

(71) Applicant: CHIPBOND TECHNOLOGY CORPORATION, Hsinchu City (TW)

(72) Inventors: Pei-Wen Wang, Taichung City (TW); Hsin-Hao Huang, Kaohsiung City (TW); Kuo-Liang Huang, Kaohsiung City (TW); Hsien-Hung Chiang, Kaohsiung City (TW)

(21) Appl. No.: 19/256,415

(22) Filed: Jul. 1, 2025

(30) Foreign Application Priority Data
Aug. 27, 2024 (TW) 113132182

(51) Int. Cl. H01L 23/34; H01L 23/498

(52) U.S. Cl. CPC H01L 23/34

(57) ABSTRACT

A chip package includes a substrate, a chip and a heat dissipation sheet. The substrate includes a carrier, a circuit layer and a solder resist layer. The circuit layer is provided on the carrier, covered by the solder resist layer and has circuit lines. The solder resist layer includes a first opening, a second opening and a covering portion located between the first and second openings. Each of the circuit line has an inner lead, a first conductive section and a second conductive section. The inner lead is visible from the first opening and electrically connected to the chip, the first conductive section is covered by the covering portion, and the second conductive section is visible from the second opening. The heat dissipation sheet is adhered to the second conductive section via an electrically insulative adhesive. Thus, thermal conductivity performance and flexibility of the chip package can be improved.

### CROSS-REFERENCE TO RELATED APPLICATIONS

This application claims priority to R.O. C Patent Application No. 113132182 filed Aug. 27, 2024, the disclosure of which is hereby incorporated by reference in its entirety.

### FIELD OF THE INVENTION

This invention relates to a chip package and its substrate, and more particularly to a chip package with improved thermal conductivity performance and flexibility by a heat dissipation sheet contacting a circuit layer on a substrate.

### BACKGROUND OF THE INVENTION

The higher the IC operation speed, the higher the chip temperature. For this reason, a heat dissipation sheet is usually provided on a chip to lower chip temperature. However, heat dissipation efficiency of conventional heat dissipation sheet may be not enough to lower chip temperature due to chip miniaturization, and chips may be damaged or operated at low speed.

### SUMMARY OF THE INVENTION

One object of the present invention is to provide a chip package which includes a substrate, a chip and a heat dissipation sheet covering the substrate and the chip, and the heat dissipation sheet is adhered to a circuit layer visible from an opening of a solder resist layer to improve heat dissipation performance of the chip package.

A chip package of the present invention includes a substrate, a chip and a heat dissipation sheet. The substrate includes a carrier, a circuit layer and a solder resist layer. The circuit layer is provided on the carrier, covered by the solder resist layer and has circuit lines. Each of the circuit lines has an inner lead, a first conductive section, a second conductive section and an outer lead. The first conductive section is located between the inner lead and the second conductive section, and the second conductive section is located between the first conductive section and the outer lead. The solder resist layer includes a first opening, a second opening and a first covering portion located between the first and second openings. The inner lead is visible from the first opening, the first conductive section is covered by the first covering portion, and the second conductive section is visible from the second opening. The chip is mounted on the substrate and electrically connected to the inner lead. The heat dissipation sheet covers the substrate and the chip and includes a heat dissipation layer and an electrically insulative adhesive. The heat dissipation layer is adhered to the second conductive section visible from the second opening via the electrically insulative adhesive.

A substrate of the present invention includes a carrier, a circuit layer and a solder resist layer. The circuit layer is provided on the carrier, covered by the solder resist layer and has circuit lines. Each of the circuit lines has an inner lead, a first conductive section, a second conductive section and an outer lead. The first conductive section is located between the inner lead and the second conductive section, and the second conductive section is located between the first conductive section and the outer lead. The solder resist layer includes a first opening, a second opening and a first covering portion located between the first and second openings. The inner lead is visible from the first opening and used to be electrically connected to a chip, the first conductive section is covered by the first covering portion, and the second conductive section is visible from the second opening and used to be adhered by a heat dissipation layer of a heat dissipation sheet via an electrically insulative adhesive.

The heat dissipation layer is adhered to the second conductive section visible from the second opening via the electrically insulative adhesive, thus, the heat generated by the chip can be conducted to the heat dissipation sheet through the second conductive section to improve heat dissipation efficiency of the chip package of the present invention.

### BRIEF DESCRIPTION OF DRAWINGS

FIG. 1 is a top view diagram illustrating a chip package in accordance with one embodiment of the present invention.

FIG. 2 is a cross-section view diagram illustrating the chip package in accordance with one embodiment of the present invention.

FIG. 3 is a top view diagram illustrating a chip package in accordance with another embodiment of the present invention.

FIG. 4 is a top view diagram illustrating a chip package in accordance with a further another embodiment of the present invention.

### DETAILED DESCRIPTION OF THE INVENTION

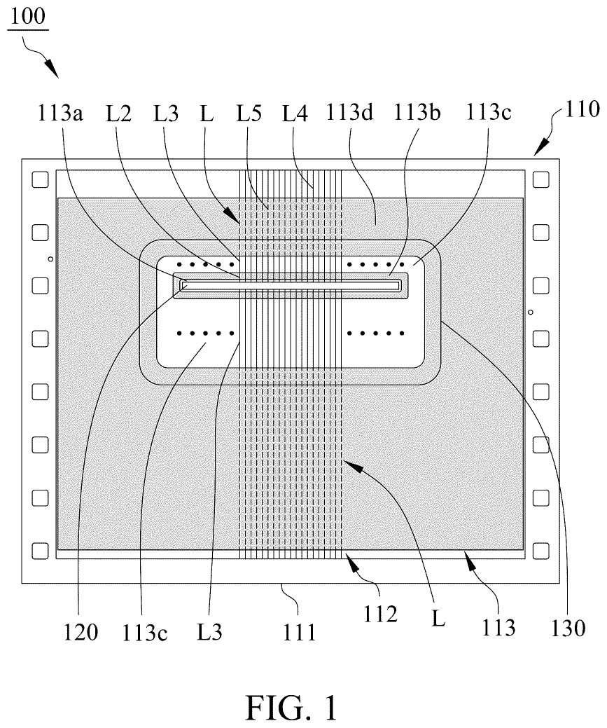

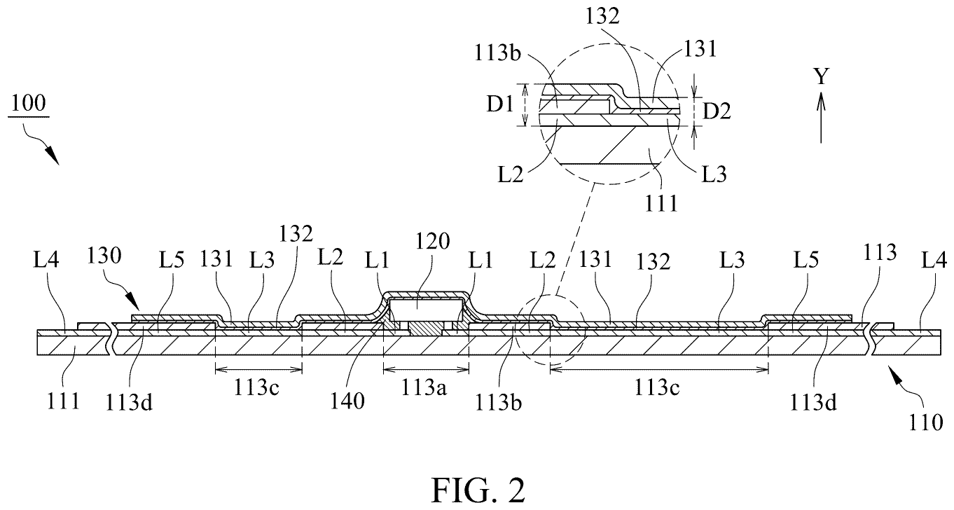

With reference to FIGS. 1 and 2, a chip package 100 includes a substrate 110, a chip 120 and a heat dissipation sheet 130. The substrate 110 includes a carrier 111, a circuit layer 112 and a solder resist layer 113. The carrier 111 may be made of polyimide (PI) or other flexible material. The circuit layer 112 is provided on the carrier 111 and covered by the solder resist layer 113. The chip 120 is mounted on the substrate 110 and electrically connected to the circuit layer 112. The heat dissipation sheet 130 is provided to cover the substrate 110 and the chip 120.

With reference to FIGS. 1 and 2, the circuit layer 112 has circuit lines L each having an inner lead L1, a first conductive section L2, a second conductive section L3 and an outer lead L4. The first conductive section L2 is located between the inner lead L1 and the second conductive section L3, and the second conductive section L3 is located between the first conductive section L2 and the outer lead L4. In this embodiment, each of the circuit lines L further has a third conductive section L5 which is located between the second conductive section L3 and the outer lead L4.

With reference to FIGS. 1 and 2, the solder resist layer 113 has a first opening 113a, a first covering portion 113b and at least one second opening 113c. The first covering portion 113b is located between the first opening 113a and the second opening 113c. In this embodiment, the first covering portion 113b surrounds the first opening 113a, and the second opening 113c surrounds the first opening 113a and the first covering portion 113b. In another embodiment as shown in FIG. 4, the second opening 113c is located on one side of the first opening 113a. While the solder resist layer 113 has more than one second opening 113c, the second openings 113c may be not connected to one another and may be arranged on different sides of the first opening 113a.

Referring to FIGS. 1 and 2, the inner lead L1 is visible from the first opening 113a, the first conductive section L2 is covered by the first covering portion 113b of the solder resist layer 113, and the second conductive section L3 is visible from the second opening 113c. In this embodiment, the solder resist layer 113 further has a second covering portion 113d. The second opening 113c is located between the first covering portion 113b and the second portion 113d, the second covering portion 113d covers the third conductive section L5 but not covers the outer lead L4 which is provided for electrical connection to external electronic device (not shown, e.g. panel).

With reference to FIGS. 1 and 2, the chip 120 is mounted in the first opening 113a and electrically connected to the inner lead L1, and preferably, a filling material 140 is provided between the substrate 110 and the chip 120. The heat dissipation sheet 130 includes a heat dissipation layer 131 and an electrically insulative adhesive 132, the heat dissipation layer 131 is adhered to the second conductive section L3 which is visible from the second opening 113c by the electrically insulative adhesive 132. Accordingly, the heat generated by the chip 120 can be conducted to the heat dissipation sheet 130, which is adhered to the second conductive section L3, via the inner lead L1, the first conductive section L2 and the second conductive section L3. The contact area of the heat dissipation sheet 130 contacting the heat source, such as the chip 120 and the circuit layer 112, can be increased to improve heat dissipation efficiency of the chip package 110. In this embodiment, the heat dissipation layer 131 is adhered to the first covering portion 113b and the second covering portion 113d by the electrically insulative adhesive 132, thus edge warpage of the first covering portion 113b and the second covering portion 113d located on both sides of the second opening 113c is limited to prevent the solder resist layer 113 from peeling off.

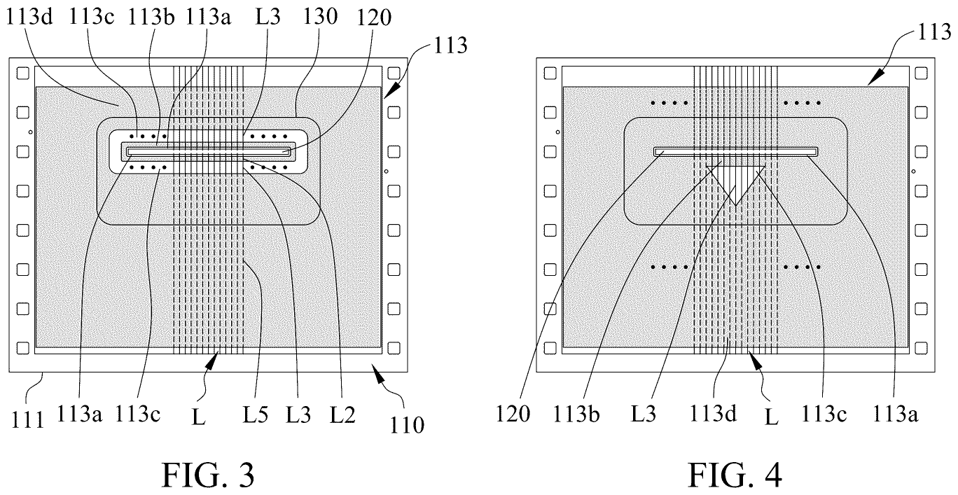

With reference to FIGS. 1, 3 and 4, the area of the second opening 113c is smaller than that of the heat dissipation sheet 130 such that the heat dissipation sheet 130 can cover the second opening 113c totally. Furthermore, the heat dissipation layer 131 is adhered to the first and second covering sections 113b and 113d via the electrically insulative adhesive 132, thereby preventing moisture from penetrating the second opening 113c. The differences of the second openings 113c shown in FIGS. 1, 3 and 4 are shape and area. The shape and area of the second opening 113c can be adjusted according to different heat dissipation requirements, and the shape of the second opening 113c can be rectangle, triangle, trapezoid or others.

With reference to FIG. 2, along a direction Y, the distance from the first conductive section L2 to the heat dissipation layer 131 is defined as a first thickness D1, and the distance from the second conductive section L3 to the heat dissipation layer 131 is defined as a second thickness D2. In this embodiment, the second thickness D2 is less than the first thickness D1. When the chip package 100 is mounted in a curved electronic product (e.g. curved panel), the flexibility of the chip package 100 is enough and available to reduce shear stress generated between the chip 120 and the inner lead L1 due to the second thickness D2 is designed to be less than the first thickness D1. Consequently, short circuit caused by the chip 120 separated from the inner lead L1 can be avoided.

With reference to FIG. 2, the heat dissipation layer 131 is adhered to the chip 120 and the filling material 140 via the electrically insulative adhesive 132 in this embodiment. And the heat dissipation layer 131 can be adhered to the chip 120 directly in other embodiments.

While this invention has been particularly illustrated and described in detail with respect to the preferred embodiments thereof, it will be clearly understood by those skilled in the art that is not limited to the specific features shown and described and various modified and changes in form and details may be made without departing from the scope of the claims.

1. A chip package comprising:
a substrate including a carrier, a circuit layer and a solder resist layer, the circuit layer is provided on the carrier, covered by the solder resist layer and includes a plurality of circuit lines, each of the plurality of circuit lines has an inner lead, a first conductive section, a second conductive section and an outer lead, the first conductive section is located between the inner lead and the second conductive section, the second conductive section is located between the first conductive section and the outer lead, the solder resist layer includes a first opening, a second opening and a first covering portion located between the first and second openings, the inner lead is visible from the first opening, the first conductive section is covered by the first covering portion, and the second conductive section is visible from the second opening;
a chip mounted on the substrate and electrically connected to the inner lead; and
a heat dissipation sheet covering the substrate and the chip, the heat dissipation sheet includes a heat dissipation layer and an electrically insulative adhesive, wherein the heat dissipation layer is adhered to the second conductive section which is visible from the second opening via the electrically insulative adhesive.

2. The chip package in accordance with claim 1, wherein an area of the second opening is smaller than that of the heat dissipation sheet, and the second opening is totally covered by the heat dissipation sheet.

3. The chip package in accordance with claim 1, wherein each of the plurality of circuit lines further has a third conductive section which is located between the second conductive section and the outer lead, the solder resist layer further includes a second covering portion which covers the third conductive section and not covers the outer lead, the second opening is located between the first and second covering portions.

4. The chip package in accordance with claim 3, wherein the heat dissipation layer is adhered to the first and second covering portions via the electrically insulative adhesive.

5. The chip package in accordance with claim 1, wherein a first thickness between the first conductive section and the heat dissipation layer is greater than a second thickness between the second conductive section and the heat dissipation layer.

6. The chip package in accordance with claim 2, wherein a first thickness between the first conductive section and the heat dissipation layer is greater than a second thickness between the second conductive section and the heat dissipation layer.

7. The chip package in accordance with claim 3, wherein a first thickness between the first conductive section and the heat dissipation layer is greater than a second thickness between the second conductive section and the heat dissipation layer.

8. The chip package in accordance with claim 4, wherein a first thickness between the first conductive section and the heat dissipation layer is greater than a second thickness between the second conductive section and the heat dissipation layer.

9. The chip package in accordance with claim 1, wherein the first opening and the first covering portion are surrounded by the second opening.

10. The chip package in accordance with claim 9, wherein the first opening is surrounded by the first covering portion.

11. A substrate comprising:
a carrier;
a circuit layer provided on the carrier and including a plurality of circuit lines, each of the plurality of circuit lines has an inner lead, a first conductive section, a second conductive section and an outer lead, the first conductive section is located between the inner lead and the second conductive section, and the second conductive section is located between the first conductive section and the outer lead; and
a solder resist layer covering the circuit layer and including a first opening, a second opening and a first covering portion, the first covering portion is located between the first and second openings, the inner lead is visible from the first opening and is configured to be electrically connected to a chip, and the first conductive section is covered by the first covering portion, wherein the second conductive section is visible from the second opening and is configured to be adhered by a heat dissipation layer of a heat dissipation sheet via an electrically insulative adhesive.

12. The substrate in accordance with claim 11, wherein each of the plurality of circuit lines further has a third conductive section which is located between the second conductive section and the outer lead, the solder resist layer further includes a second covering portion which covers the third conductive section and not covers the outer lead, the second opening is located between the first and second covering portions.

13. The substrate in accordance with claim 12, wherein the first and second covering portions are configured to be adhered by the heat dissipation layer via the electrically insulative adhesive.

14. The substrate in accordance with claim 11, wherein the first opening and the first covering portion are surrounded by the second opening.

15. The substrate in accordance with claim 14, wherein the first opening is surrounded by the first covering portion.
